(19) United States
(12) Patent Application Publication
(10) Pub. No.: US 2020/0359534 A1
(43) Pub. Date: Nov. 12, 2020

(54) RADIO FREQUENCY/ELECTROMAGNETIC INTERFERENCE SHIELDING SRUCTURES CONTAINING PLASTIC MATERIALS

(71) Applicant: Intel Corporation, Santa Clara, CA (US)

(72) Inventors: Richard Perry, Portland, OR (US); Russell Snyder, Santa Clara, CA (US); Srinath Yerakondappagari, Hillsboro, OR (US); Jesse Melhorn, Keizer, OR (US)

(73) Assignee: Intel Corporation, Santa Clara, CA (US)

(21) Appl. No.: 16/407,635

(22) Filed: May 9, 2019

(51) Int. Cl. H05K 9/00

(52) U.S. Cl. CPC H05K 9/003; H05K 9/0032; H05K 9/0083; H05K 9/0088

(57) ABSTRACT

An electromagnetic shielding structure may be formed having a planar structure and at least one footing projecting from the planar structure, wherein at least one of the planar structure and the at least one footing comprises a heat resistant plastic core and an electrically conductive material abutting at least a portion of the heat resistant plastic core. In one embodiment, an integrated circuit assembly may be formed comprising at least one integrated circuit device electrically attached to an electronic substrate and the electromagnetic shield structure electrically attached to the electronic substrate adjacent to the at least one integrated circuit device.

### TECHNICAL FIELD

Embodiments of the present description generally relate to radio frequency/electromagnetic interference shielding for integrated circuit assemblies, and, more specifically, to forming a radio frequency/electromagnetic interference shield from a plastic material.

### BACKGROUND

The integrated circuit industry is continually striving to produce ever faster, smaller, and thinner integrated circuit packages for use in various electronic products, including, but not limited to, computer servers and portable products, such as portable computers, electronic tablets, cellular phones, digital cameras, and the like.

As integrated circuit products and packages become smaller, the integrated circuit devices within the products and packages are positioned closer to one another. Furthermore, greater power levels are being used by the integrated circuit products and packages. The closeness of the integrated circuit devices and the increased power levels can give rise to problems with electromagnetic interference. Electromagnetic interference occurs when low-frequency electromagnetic fields are generated by the integrated circuit devices, which may interfere with the operation of other integrated circuits within the products or packages. Additionally, when wireless components are incorporated into the integrated circuit products and packages, high-frequency electromagnetic radiation is generated, which may also interfere with the operation of other integrated circuits within the products or packages.

One approach to reduce this interference is through the use of electromagnetic shielding structures (known as Faraday cages), such as frames, shields, or cages, which are a highly electrically conductive structures that are grounded and enclose or surround a portion of selected integrated circuit devices within a product or package. Such structures not only contain electromagnetic fields generated by the integrated circuit device(s) that it encloses or surrounds, but also prevents external or ambient electromagnetic fields, such as radio frequency energy, from affecting the functionality of the enclosed integrated circuit device(s), as will be understood to those skilled in the art.

Electromagnetic shielding structures are generally made of various metals, such as tin-plated steel, or metal alloys, such as nickel/silver alloy, which are stamped and/or folded to form an appropriate shape. However, such electromagnetic shielding structures, whether consisting of a single piece or multiple pieces, may have gaps at corners due to the stamping and/or folding process, and will have design constraints with regard to shape, thickness, and coplanarity, as will be understood to those skilled in the art. In particular, such electromagnetic shield structures cannot be less than about 0.1mm thick, when metals and metal alloys are used. This minimum thickness is necessary to prevent electromagnetic shield structures from deforming due to physical and/or temperature induced stresses during manufacturing and assembly processes, such as reflow and laser marking. Furthermore, such electromagnetic shielding structures can only be “cut and formed” which limits shapes that can be designed, and it is difficult to make compartment to separate integrated circuit devices effectively. Moreover, it is difficult to design an electromagnetic shielding structure that is effective for frequencies above about 28 gigahertz, as will be understood to those skilled in the art.

The limitations of all metal electromagnetic shielding structures can be addressed by forming core structures from plastic materials with a metal material being plated on the core structures. However, such electromagnetic shielding structures, as presently fabrication, cannot withstand soldering processes necessary to attach them to a substrate in an integrated circuit product or package.

### BRIEF DESCRIPTION OF THE DRAWINGS

The subject matter of the present disclosure is particularly pointed out and distinctly claimed in the concluding portion of the specification. The foregoing and other features of the present disclosure will become more fully apparent from the following description and appended claims, taken in conjunction with the accompanying drawings. It is understood that the accompanying drawings depict only several embodiments in accordance with the present disclosure and are, therefore, not to be considered limiting of its scope. The disclosure will be described with additional specificity and detail through use of the accompanying drawings, such that the advantages of the present disclosure can be more readily ascertained, in which:

FIG. 1 is a side cross-sectional view of an electromagnetic shielding structure, according to one embodiment of the present description.

FIG. 2 is an oblique plan view of the electromagnetic shielding structure of FIG. 1, according to an embodiment of the present description.

FIG. 3 is an oblique plan view of the electromagnetic shielding structure along view A-A of FIG. 2, according to one embodiment of the present description.

FIG. 4 is a side cross-sectional view of an integrated circuit assembly including the electromagnetic shielding structure of FIG. 1, according to one embodiment of the present description.

FIG. 5 is a side cross-sectional view of a portion of electromagnetic shielding structure showing the structure of an electrically conductive material on a core, according to one embodiment of the present description.

FIG. 6 is a side cross-sectional view of an integrated circuit assembly including an electromagnetic shielding structure electrically attached to a ground plane within an electronic substrate, according to one embodiment of the present description.

FIG. 7 is an oblique plan view of the electromagnetic shielding structure along view A-A of FIG. 2, wherein the electromagnetic shielding structure includes multiple compartments, according to another embodiment of the present description.

FIG. 8 is a side cross-sectional view of an integrated circuit assembly including the electromagnetic shielding structure of FIG. 7, according to one embodiment of the present description.

FIG. 9 is a side cross-sectional view of an integrated circuit assembly including an electromagnetic shielding structure acting as a heat dissipation device, according to one embodiment of the present description.

FIG. 10 is an oblique plan view of an electromagnetic shielding structure, according to another embodiment of the present description.

FIG. 11 is an oblique plan view of an electromagnetic shielding structure having at least one opening extending therethrough wherein the at least one opening may be utilized in the formation of the thermal dissipation path, according to various embodiments of the present description.

FIG. 12 is a cross-sectional view of the electromagnetic shielding structure of FIG. 7 as a part of an integrated circuit assembly, wherein the electromagnetic shielding structure has at least one opening extending therethrough wherein the at least one opening may be utilized in the formation of the thermal dissipation path, according to various embodiments of the present description.

FIG. 13 is an oblique plan view of electromagnetic shielding structures having a plurality of openings extending therethrough, wherein electrically conductive material within the plurality of opening form a thermal dissipation path, according to various embodiments of the present description.

FIG. 14 is a cross-sectional view of the electromagnetic shielding structure of FIG. 8 as a part of an integrated circuit assembly, according to various embodiments of the present description.

FIG. 15 is a side cross-sectional view of an electromagnetic shielding structure having a two-piece design, according to one embodiment of the present description.

FIG. 16 is a side cross-sectional view of an electromagnetic shielding structure having a multiple piece design, according to another embodiment of the present description.

FIG. 17 is a flow chart of a process of fabricating an integrated circuit assembly, according to an embodiment of the present description.

FIG. 18 is an electronic system, according to one embodiment of the present description.

### DETAILED DESCRIPTION

In the following detailed description, reference is made to the accompanying drawings that show, by way of illustration, specific embodiments in which the claimed subject matter may be practiced. These embodiments are described in sufficient detail to enable those skilled in the art to practice the subject matter. It is to be understood that the various embodiments, although different, are not necessarily mutually exclusive. For example, a particular feature, structure, or characteristic described herein, in connection with one embodiment, may be implemented within other embodiments without departing from the spirit and scope of the claimed subject matter. References within this specification to “one embodiment” or “an embodiment” mean that a particular feature, structure, or characteristic described in connection with the embodiment is included in at least one implementation encompassed within the present description. Therefore, the use of the phrase “one embodiment” or “in an embodiment” does not necessarily refer to the same embodiment. In addition, it is to be understood that the location or arrangement of individual elements within each disclosed embodiment may be modified without departing from the spirit and scope of the claimed subject matter. The following detailed description is, therefore, not to be taken in a limiting sense, and the scope of the subject matter is defined only by the appended claims, appropriately interpreted, along with the full range of equivalents to which the appended claims are entitled. In the drawings, like numerals refer to the same or similar elements or functionality throughout the several views, and that elements depicted therein are not necessarily to scale with one another, rather individual elements may be enlarged or reduced in order to more easily comprehend the elements in the context of the present description.

The terms “over”, “to”, “between” and “on” as used herein may refer to a relative position of one layer with respect to other layers. One layer “over” or “on” another layer or bonded “to” another layer may be directly in contact with the other layer or may have one or more intervening layers. One layer “between” layers may be directly in contact with the layers or may have one or more intervening layers.

The term “package” generally refers to a self-contained carrier of one or more dice, where the dice are attached to the package substrate, and may be encapsulated for protection, with integrated or wire-boned interconnects between the dice and leads, pins or bumps located on the external portions of the package substrate. The package may contain a single die, or multiple dice, providing a specific function. The package is usually mounted on a printed circuit board for interconnection with other packaged integrated circuits and discrete components, forming a larger circuit.

Here, the term “cored” generally refers to a substrate of an integrated circuit package built upon a board, card or wafer comprising a non-flexible stiff material. Typically, a small printed circuit board is used as a core, upon which integrated circuit device and discrete passive components may be soldered. Typically, the core has vias extending from one side to the other, allowing circuitry on one side of the core to be coupled directly to circuitry on the opposite side of the core. The core may also serve as a platform for building up layers of conductors and dielectric materials.

Here, the term “coreless” generally refers to a substrate of an integrated circuit package having no core. The lack of a core allows for higher-density package architectures. as the through-vias have relatively large dimensions and pitch compared to high-density interconnects.

Here, the term “land side”, if used herein, generally refers to the side of the substrate of the integrated circuit package closest to the plane of attachment to a printed circuit board, motherboard, or other package. This is in contrast to the term “die side”, which is the side of the substrate of the integrated circuit package to which the die or dice are attached.

Here, the term “dielectric” generally refers to any number of non-electrically conductive materials that make up the structure of a package substrate. For purposes of this disclosure, dielectric material may be incorporated into an integrated circuit package as layers of laminate film or as a resin molded over integrated circuit dice mounted on the substrate.

Here, the term “metallization” generally refers to metal layers formed over and through the dielectric material of the package substrate. The metal layers are generally patterned to form metal structures such as traces and bond pads. The metallization of a package substrate may be confined to a single layer or in multiple layers separated by layers of dielectric.

Here, the term “bond pad” generally refers to metallization structures that terminate integrated traces and vias in integrated circuit packages and dies. The term “solder pad” may be occasionally substituted for “bond pad” and carries the same meaning.

Here, the term “solder bump” generally refers to a solder layer formed on a bond pad. The solder layer typically has a round shape, hence the term “solder bump”.

Here, the term “substrate” generally refers to a planar platform comprising dielectric and metallization structures. The substrate mechanically supports and electrically couples one or more IC dies on a single platform, with encapsulation of the one or more IC dies by a moldable dielectric material. The substrate generally comprises solder bumps as bonding interconnects on both sides. One side of the substrate, generally referred to as the “die side”, comprises solder bumps for chip or die bonding. The opposite side of the substrate, generally referred to as the “land side”, comprises solder bumps for bonding the package to a printed circuit board.

Here, the term “assembly” generally refers to a grouping of parts into a single functional unit. The parts may be separate and are mechanically assembled into a functional unit, where the parts may be removable. In another instance, the parts may be permanently bonded together. In some instances, the parts are integrated together.

Throughout the specification, and in the claims, the term “connected” means a direct connection, such as electrical, mechanical, or magnetic connection between the things that are connected, without any intermediary devices.

The term “coupled” means a direct or indirect connection, such as a direct electrical, mechanical, magnetic or fluidic connection between the things that are connected or an indirect connection, through one or more passive or active intermediary devices.

The term “circuit” or “module” may refer to one or more passive and/or active components that are arranged to cooperate with one another to provide a desired function. The term “signal” may refer to at least one current signal, voltage signal, magnetic signal, or data/clock signal. The meaning of “a,” “an,” and “the” include plural references. The meaning of “in” includes “in” and “on.”

The vertical orientation is in the z-direction and it is understood that recitations of “top”, “bottom”, “above” and “below” refer to relative positions in the z-dimension with the usual meaning. However, it is understood that embodiments are not necessarily limited to the orientations or configurations illustrated in the figure.

The terms “substantially,” “close,” “approximately,” “near,” and “about,” generally refer to being within +/−10% of a target value (unless specifically specified). Unless otherwise specified the use of the ordinal adjectives “first,” “second,” and “third,” etc., to describe a common object, merely indicate that different instances of like objects to which are being referred and are not intended to imply that the objects so described must be in a given sequence, either temporally, spatially, in ranking or in any other manner.

For the purposes of the present disclosure, phrases “A and/or B” and “A or B” mean (A), (B), or (A and B). For the purposes of the present disclosure, the phrase “A, B, and/or C” means (A), (B), (C), (A and B), (A and C), (B and C), or (A, B and C).

Views labeled “cross-sectional”, “profile” and “plan” correspond to orthogonal planes within a cartesian coordinate system. Thus, cross-sectional and profile views are taken in the x-z plane, and plan views are taken in the x-y plane. Typically, profile views in the x-z plane are cross-sectional views. Where appropriate, drawings are labeled with axes to indicate the orientation of the figure.

Embodiments of the present description include an electromagnetic shielding structure comprising a planar structure and at least one footing projecting from the planar structure, wherein at least one of the planar structure and the at least one footing comprises a heat resistant plastic core and an electrically conductive material abutting at least a portion of the heat resistant plastic core. In one embodiment, an integrated circuit assembly may be formed comprising at least one integrated circuit device electrically attached to an electronic substrate and the electromagnetic shield structure electrically attached to the electronic substrate adjacent to the at least one integrated circuit device.

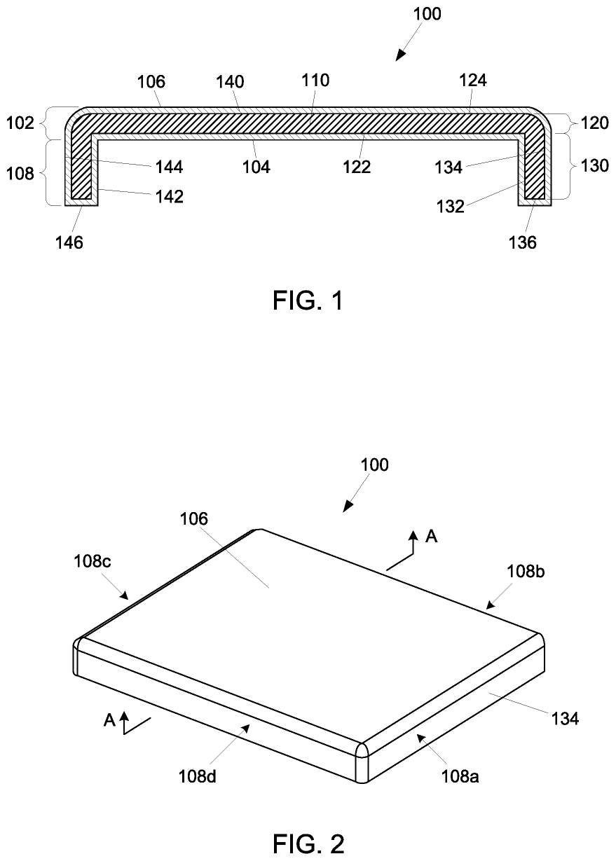

As shown in FIG. 1, an electromagnetic shielding structure 100 may include a core 110 having an electrically conductive material 140 formed thereon. The core 110 may be comprise a planar structure 120 having a first surface 122 and an opposing second surface 124, and may have at least one extension 130 projecting from the first surface 122 of the planar structure 120 of the core 110, wherein the at least one extension 130 may include at least one inner sidewall 132, at least one outer sidewall 134, and at least one attachment surface 136 between the at least one inner sidewall 132 and the at least one outer sidewall 134. In an embodiment, the at least one extension 130 may extend substantially perpendicular to the first surface 122 of the planar structure 120 of the core 110. It is understood that the term substantially perpendicular includes the at least one extension 130 being plus or minus 5 degrees from 90 degrees.

In the embodiments of the present description, the core 110 is fabricated from a plastic material which can withstand repeated heating cycles of temperatures of about 260 degrees Celsius and greater (hereinafter defined at be a “heat resistant plastic material”) without experiencing thermal degradation, such that the electromagnetic shielding structure 100 may be soldered to a substrate (as will be discussed). The core 110 may be formed by any appropriate process, including, but not limited to a molding process. The heat resistant plastic material may be any appropriate organic polymer, including, but not limited to, acrylic, polyester, silicone, polyurethane, combination thereof, and the like, and may include filler materials, including, but not limited to, starch, cellulose, zinc oxide, glass fibers, and the like. In a specific embodiment, the core 110 may be formed from a heat resistant plastic material comprising a liquid crystal polymer with a glass fiber filler material.

The electrically conductive material 140 formed on the core 110 may be any appropriate material, including, but not limited to at least one metal and alloys of more than one metal. In one embodiment, the electrically conductive material 140 may comprise copper, tin, silver, gold, nickel, aluminum, zinc, steel, alloys thereof, such as nickel/silver, and the like, and may having one or more layers thereof. In a specific embodiment, the electrically conductive material 140 may formed from at least one layer of tin and at least one layer of copper. The electrically conductive material 140 may be formed on the core 110 may any known process, including, but not limited to, deposition, lamination, plating, and the like. In a specific embodiment, the electrically conductive material 140 is plated on the core 110. The processes for the plating of the electrically conductive material 140 are well known in the art and for purposes of brevity and conciseness will not be described herein. In one embodiment, the electrically conductive material 140 substantially completely encapsulates the core 110, such that all of the surfaces of the core 110 are coated with the electrically conductive material 140.

The planar structure 120 of the core 110 coated with the electrically conductive material 140 may be referred to as the planar portion 102 of the electromagnetic shielding structure 100 having a first surface 104 and an opposing second surface 106. The at least one extension 130 of the core 110 coated with the electrically conductive material 140 may be referred to as the at least one footing 108 of the electromagnetic shielding structure 100. As with the at least one extension 130 of the core 110, the at least one footing 108 of the electromagnetic shielding structure 100 may include at least one inner sidewall 142, at least one outer sidewall 144, and at least one attachment surface 146 between the at least one inner sidewall 142 and the at least one outer sidewall 144.

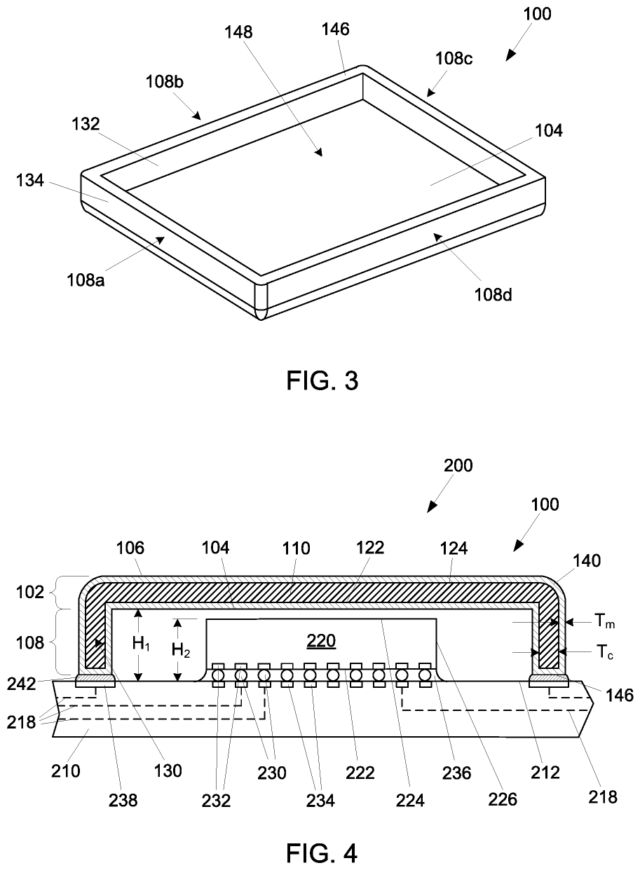

As shown in FIGS. 2 and 3, the at least one footing 108 of the electromagnetic shielding structure 100 may comprises four conjoined footings (labeled as 108a, 108b, 108c, and 108d) which forms a cavity or compartment 148 (see FIG. 3) defined by the inner sidewalls 142 of the footings 108a, 108b, 108c, and 108d, and the first surface 104 of the planar portion 102 of the electromagnetic shielding structure 100.

As shown in FIG. 4, an integrated circuit assembly 200, such as an integrated circuit package, may be formed by first providing or forming an electronic substrate 210, such as an interposer, a printed circuit board, a motherboard, or the like. At least one integrated circuit device 220 may be attached to a first surface 212 of the electronic substrate 210 with a plurality of interconnects 230. The plurality of interconnects 230 may extend between bond pads 232 formed in or on a first surface 222 (also known as the “active surface”) of the integrated circuit device 220, and substantially mirror-image bond pads 234 formed in or on the first surface 212 of the electronic substrate 210. The at least one integrated circuit device 220 may further include a second surface 224 (also known as the “back surface”) opposing the first surface 222 and at least one side 226 extending between the first surface 222 and the second surface 224 of the at least one integrated circuit device 220. The least one integrated circuit device 220 may be any appropriate device, including, but not limited to, a microprocessor, a multichip package, a chipset, a graphics device, a wireless device, a memory device, an application specific integrated circuit device, combinations thereof, stacks thereof, or the like. The interconnects 230 may be any appropriate electrically conductive material or structure, including but not limited to, solder balls, metal bumps or pillars, metal filled epoxies, or a combination thereof. In one embodiment, the interconnects 230 may be solder balls formed from tin, lead/tin alloys (for example, 63% tin/37% lead solder), and high tin content alloys (e.g. 90% or more tin—such as tin/bismuth, eutectic tin/silver, ternary tin/silver/copper, eutectic tin/copper, and similar alloys). In another embodiment, the interconnects 230 may be copper bumps or pillars. In a further embodiment, the interconnects 230 may be metal bumps or pillars coated with a solder material.

An underfill material 236, such as an epoxy material, may be disposed between the first surface 222 of the integrated circuit device 220 and the first surface 212 of the electronic substrate 210, and surrounding the plurality of interconnects 230. As will be understood to those skilled in the art, the underfill material 236 may be dispensed between the first surface 222 of the integrated circuit device 220 and the first surface 212 of the electronic substrate 210 as a viscous liquid and then hardened with a curing process. The underfill material 236 may also be a molded underfill material. The underfill material 236 may provide structural integrity and may prevent contamination, as will be understood to those skilled in the art.

As further shown in FIG. 4, the electronic substrate 210 may provide electrical communication through conductive routes 218 (illustrated as dashed lines) between the integrated circuit device 220 and external components (not shown). These conduction routes 218 may be referred to herein as “metallization”. As will be understood to those skilled in the art, the bond pads 232 of the integrated circuit device 220 may be in electrical communication with integrated circuitry (not shown) within the integrated circuit device 220.

The electronic substrate 210 may comprise a plurality of dielectric material layers (not shown in FIG. 4), which may include build-up films and/or solder resist layers, and may be composed of an appropriate dielectric material, including, but not limited to, bismaleimide triazine resin, fire retardant grade 4 material, polyimide material, silica filled epoxy material, glass reinforced epoxy material, as well as laminates or multiple layers thereof, and the like, as well as low-k and ultra low-k dielectrics (dielectric constants less than about 3.6), including, but not limited to, carbon doped dielectrics, fluorine doped dielectrics, porous dielectrics, organic polymeric dielectrics, and the like. The conductive routes 218 may be a combination of conductive traces (not shown) and conductive vias (not shown) that extend through the plurality of dielectric material layers (not shown). These conductive traces and conductive vias, and processes of forming the same, are well known in the art and are not shown in FIG. 4 for purposes of clarity. The conductive traces and the conductive vias may be made of any appropriate conductive material, including but not limited to, metals, such as copper, silver, nickel, gold, and aluminum, alloys thereof, and the like. As will be understood by those skilled in the art, the electronic substrate 210 may be a cored substrate or a coreless substrate.

As shown in FIG. 4, the integrated circuit assembly 200 may include the at least one electromagnetic interference structure 100 electrically attached to the electronic substrate 210 adjacent to the at least one integrated circuit device 220. As will be understood, the at least one electromagnetic interference structure 100 is electrically attached to electrical ground within the electronic substrate 210. In one embodiment, the at least one footing 108 of the electromagnetic shielding structure 100 may be attached to the electronic substrate 210 by a solder material 242, disposed between the attachment surface 146 of the at least one footing 108 of the electromagnetic shielding structure 100 and at least one bond pad 238 on or in the first surface 212 of the electronic substrate 210. In various embodiments, the solder material 242 may be tin, lead/tin alloys (for example, 63% tin/37% lead solder), and high tin content alloys (e.g. 90% or more tin—such as tin/bismuth, eutectic tin/silver, ternary tin/silver/copper, eutectic tin/copper, and similar alloys).

In one embodiment, the electromagnetic shielding structure 100 may be attached to the first surface 212 of the electronic substrate 210, such that the first surface 104 of the planar portion 102 of the electromagnetic shielding structure 100 spans, but does not necessarily directly contact the second surface 224 (e.g. opposing the first surface 222) of the integrated circuit device 220.

As will be understood, the embodiments of the present description may permit unlimited design flexibility to form custom shapes with regard to shape, internal height H₁ (z-direction), and core thickness T_{c}, while forming the electromagnetic shielding structure 100 that substantially encloses the integrated circuit device 220 of the integrated circuit assembly 200 (in conjunction with the electronic substrate 210) to contain or block radio frequency/electromagnetic emissions. In one embodiment, the electromagnetic shielding structure 100 may be effective to contain or block radio frequency/electromagnetic emissions between about 1 megahertz to over 70 gigahertz.

As the core 110 of the electromagnetic shielding structure 100 is formed from plastic, the internal height H₁ (z-direction) is not limited to bend constrains with known metal stamped shields. Thus, the embodiments of the present description may have the maximum internal height H₁ of the electromagnetic shielding structure 100 at about the same as the height H₂ of the integrated circuit device 220 from the electronic substrate 210 of the integrated circuit assembly 200. Furthermore, the thickness T_{c} of the core 110 may be varied to achieve a desired structural support. Additionally, as will be understood, the embodiments of the present description allow for precise dimensions and co-planarity of the electromagnetic shielding structure 100.

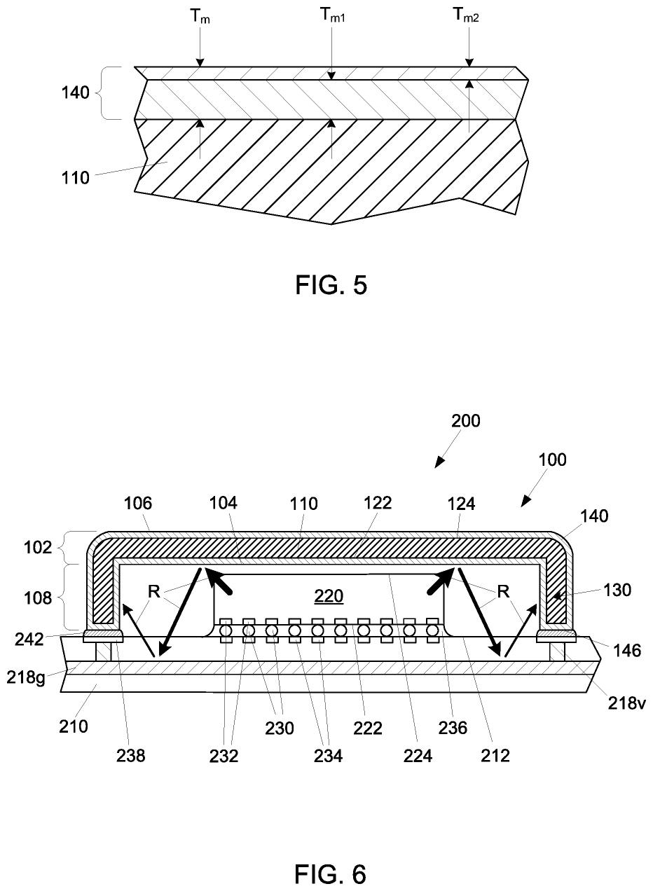

The materials used to form the electrically conductive material 140 and thickness Tₘ of the electrically conductive material 140 on the core 110 may be varied to achieve a desired shielding effect. It is understood that the thickness Tₘ (also known as “skin depth”) is specifically selected for the electrically conductive material 140 to stop a particular frequency or frequencies. In general, the lower the frequency, the thicker the electrically conductive material 140 needs to be, and vice versa. Thus, the embodiments of the present description allow for the adjustment of the material type for the electrically conductive material 140 and adjustment of the thickness Tₘ thereof to effectively block the frequency of interest. In one embodiment, as shown in the FIG. 5, the electrically conductive material 140 may comprise multiple layers (shown as a first layer 140₁ and a second layer 140₂) on the core 110. The first layer 140₁ and a second layer 140₂ may be any appropriate material, including copper, tin, silver, gold, nickel, aluminum, zinc, steel, alloys thereof, and the like. In one embodiment, the first layer 140₁ may comprise copper having a thickness T_{M1} of between about 5 and 10 microns, wherein the first layer 140₁ abuts the core 110, and the second layer 140₂ may comprise tin having a thickness T_{M2} of about 1.5. microns, wherein the second layer 140₂ abuts the first layer 140₁. The use of tin for the second layer 140₂ may protect the copper of the first layer 140₁ from corrosion and may facilitate soldering the electromagnetic shielding structure 100 to the electronic substrate 210.

In one embodiment, the electronic substrate 210 may be configured to assist in shielding. In one embodiment, shown in FIG. 6, the conductive route 218 (see FIG. 4) to which the electromagnetic shielding structure 100 is ground may be a full ground plane 218g, as known in the art, connected with at least one via 218v. As will be understood, on every reflection or “bounce” of the radio frequency signal R, the electromagnetic shield structure 100 absorbs a portion thereof. The unabsorbed portion reflects from the electromagnetic shield structure 100 to the full ground plane 108g, which absorbs a portion thereof and reflects the remainder. It is understood that each bounce reduces the power of the radio frequency signal R, which is shown as a diminishing arrow size of the representation of the radio frequency signal R.

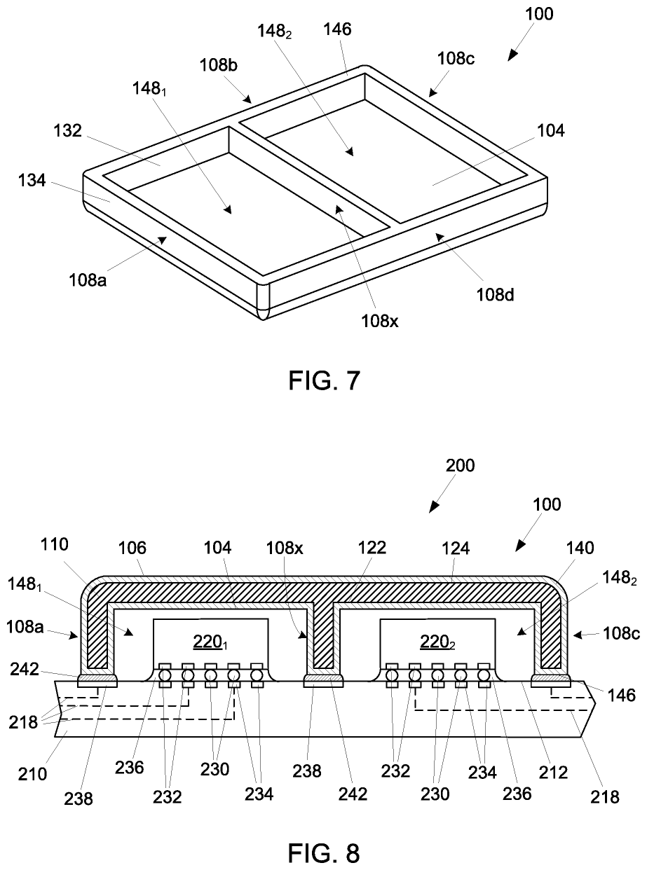

Although the electromagnetic shield structure 100 has been shown as having a single cavity or compartment 148 (see FIG. 3), the embodiments of the present description are not so limited. As shown in FIGS. 7 and 8, the electromagnetic shielding structure 100 may include multiple compartments, shown as a first compartment 148₁ and a second compartment 1482 separated by a compartment footing 108x. As shown in FIG. 8, the compartmentalized electromagnetic shield structure 100 may allow for shielding between multiple integrated circuit devices, shown as a first integrated circuit device 220₁ and a second integrated circuit device 220₂. Such a configuration may isolate the first integrated circuit device 220₁ and the second integrated circuit device 220₂, such that there is no interference between, even though they are mounted to the same electronic substrate 210.

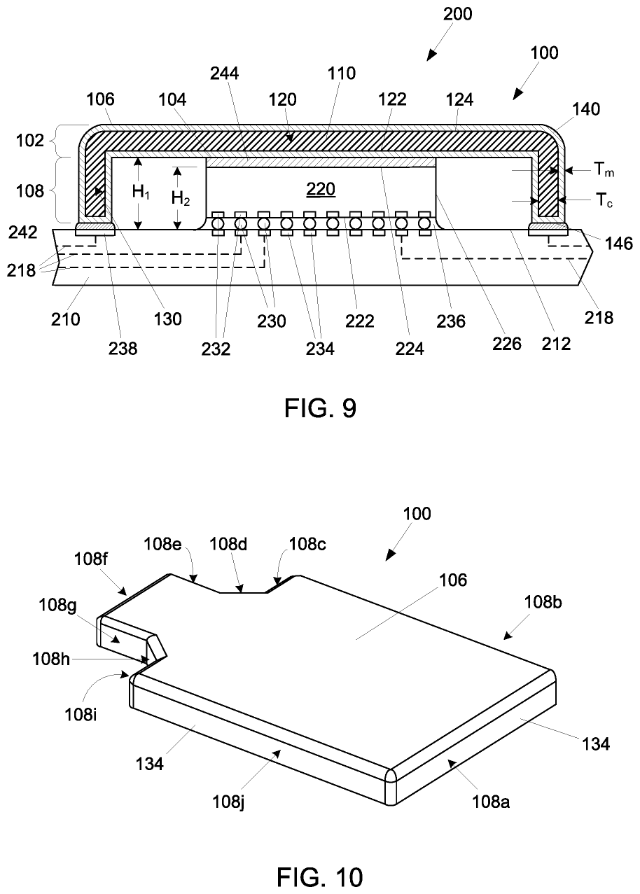

In one embodiment of the present description, as shown in FIG. 9, the electrically conductive material 140 and/or the core 110 of the electromagnetic shielding structure 100 may be sufficiently thermally conductive to act as a heat dissipation device. In such an embodiment, a thermal interface material 244, such as a grease, a polymer, a thermal gap pad, or the like, may be disposed between the first surface 104 of the planar portion 102 of the electromagnetic shielding structure 100 and the second surface 224 of the integrated circuit device 220 to facilitate heat transfer therebetween.

Although the embodiments of FIGS. 1-9 show the electronic shielding structure 100 as having a substantially rectilinear shape, the embodiments of the present description are not so limited. For example, as shown in FIG. 10, the electronic shield structure 100 may have any appropriate shape and any appropriate number of footings (shown as elements 108a-108j) to cover integrated circuit devices (such as multiple integrated circuit devices 220) of the integrated circuit assembly 200 (see FIG. 4).

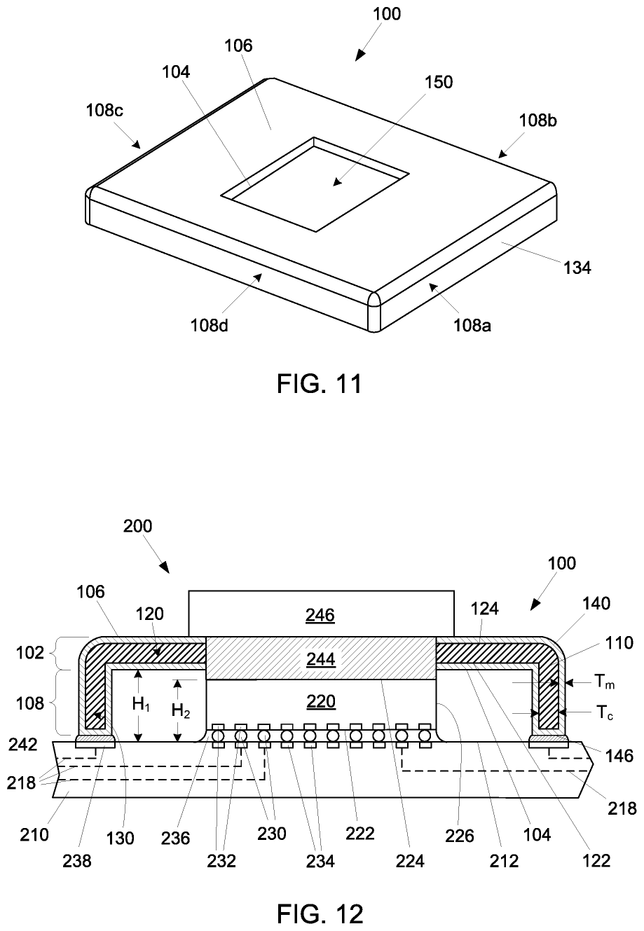

In another embodiment of the present description, as shown in FIGS. 11 and 12, the planar portion 102 of the electromagnetic shielding structure 100 may have an opening 150 formed therethrough extending from the first surface 104 to the second surface 106 thereof. As shown in FIG. 12, the thermal interface material 244 may be disposed within the opening 150 to thermally connect the integrated circuit device 220 to a heat dissipation device 246 at or above the second surface 106 of the planar portion 102 of the electromagnetic shielding structure 100. The heat dissipation device 246 may be any appropriate device including, but not limited to, a heat sink, a heat pipe, and the like.

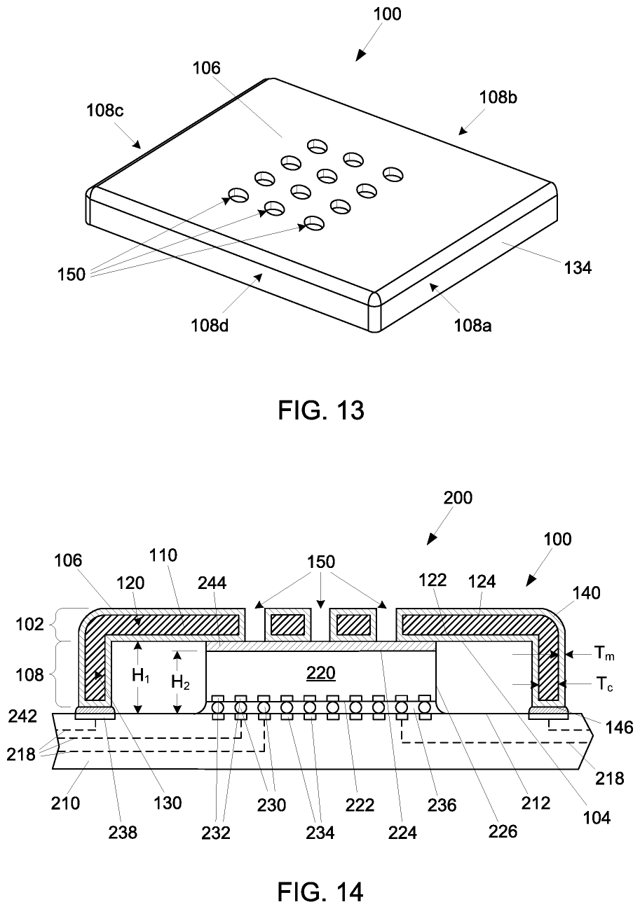

In one embodiment of the present description, the electrically conductive material 140 of the electromagnetic shielding structure 100 may also be thermally conductive. As shown in FIGS. 13 and 14, a plurality of openings 150 may be formed in the core 110 and the electrically conductive material 140 may be formed such that it extends through the openings 150. Thus, the electrically conductive material 140 within the opening 150 forms a thermal path between the integrated circuit device 220 and the second surface 106 of the planar portion 102 of the electromagnetic shielding structure 100. The plurality of openings 150 may be spaced in a manner that they do not affect the shield properties of the electromagnetic shielding structure 100, as will be understood to those skilled in the art.

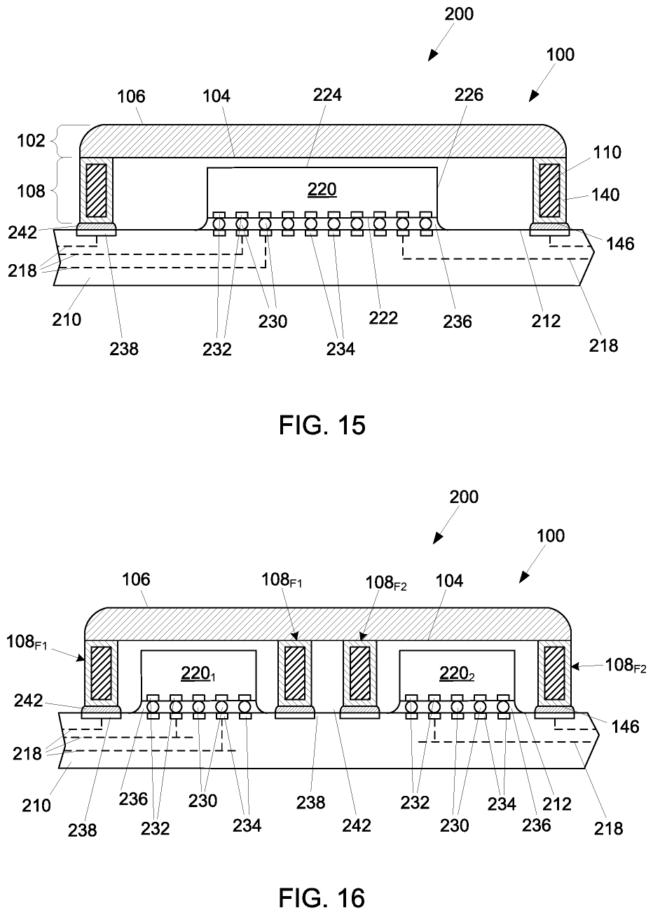

Although the embodiment of FIGS. 1-14 illustrate the electromagnetic shielding structure 100 as a single, contiguous structure, the embodiments of the present description are not so limited, as the electromagnetic shielding structure 100 may be formed from multiple components. For example, as shown in FIG. 15, the electromagnetic shielding structure 100 may be a two-piece design, wherein the planar portion 102 may be a separate structure from the at least one footing 108. As shown, the at least one footing 108 may comprise the core 110 and the electrically conductive material 140 on the core 110. The planar portion 102 may be a metal or plastic which as attached to the at least one footing 108. The planar portion 102 may be attached to the at least footing 108 in any known manner that insures a good grounding contact therebetween, such as with a snap feature. The planar portion 102 may be attached to the at least one footing 108 either before or after the at least one footing 108 is attached to the electronic substrate 210.

In a further embodiment, the electromagnetic shielding structure 100 may have a multiple piece design, according to another embodiment of the present description. In the embodiment shown in FIG. 16, the electromagnetic shielding structure 100, the at least one footing 108 of FIG. 15 may be formed as at least two fences, e.g. a first fence 108_{F1} and a second fence 108_{F2}, wherein the first fence 108_{F1} surrounds the first integrated circuit device 220₁ and the second fence 108_{F2} surrounds the second integrated circuit device 220₂, wherein a single planar portion 102 is attached to both the first fence 108_{F1} and the second fence 108_{F2}.

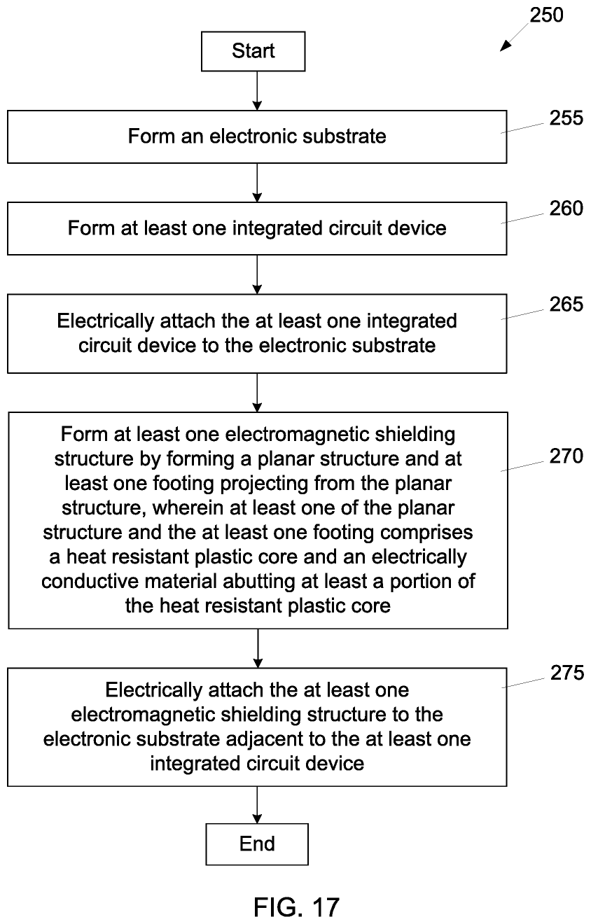

FIG. 17 is a flow chart of a process 250 of fabricating an integrated circuit assembly according to an embodiment of the present description. As set forth in block 255, an electronic substrate may be formed. At least one integrated circuit device may be formed, as set forth in block 260. As set forth in block 265, the at least one integrated circuit device may be electrically attached to the electronic substrate. At least one electromagnetic interference structure may be formed by forming a planar structure and at least one footing projecting from the planar structure, wherein at least one of the planar structure and the at least one footing comprises a heat resistant plastic core and an electrically conductive material abutting at least a portion of the heat resistant plastic core, as set forth in block 270. As set forth in block 275, the at least one electromagnetic shielding structure may be attached to the electronic substrate adjacent to the at least one integrated circuit device.

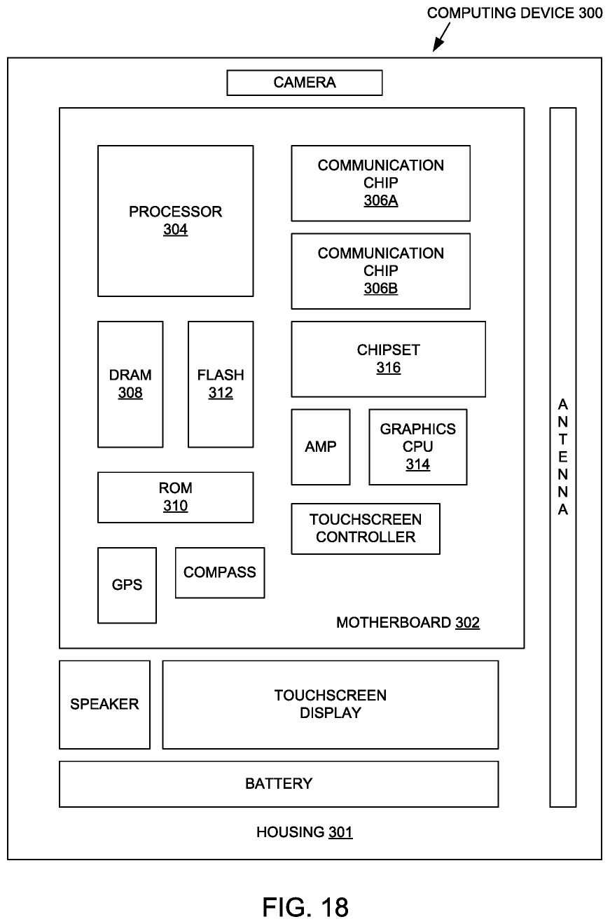

FIG. 18 illustrates an electronic or computing device 300 in accordance with one implementation of the present description. The computing device 300 may include a housing 301 having a board 302 disposed therein. The computing device 300 may include a number of integrated circuit components, including but not limited to a processor 304, at least one communication chip 306A, 306B, volatile memory 308 (e.g., DRAM), non-volatile memory 310 (e.g., ROM), flash memory 312, a graphics processor or CPU 314, a digital signal processor (not shown), a crypto processor (not shown), a chipset 316, an antenna, a display (touchscreen display), a touchscreen controller, a battery, an audio codec (not shown), a video codec (not shown), a power amplifier (AMP), a global positioning system (GPS) device, a compass, an accelerometer (not shown), a gyroscope (not shown), a speaker, a camera, and a mass storage device (not shown) (such as hard disk drive, compact disk (CD), digital versatile disk (DVD), and so forth). Any of the integrated circuit components may be physically and electrically coupled to the board 302. In some implementations, at least one of the integrated circuit components may be a part of the processor 304.

The communication chip enables wireless communications for the transfer of data to and from the computing device. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device may include a plurality of communication chips. For instance, a first communication chip may be dedicated to shorter range wireless communications such as Wi-Fi and Bluetooth and a second communication chip may be dedicated to longer range wireless communications such as GPS, EDGE, GPRS, CDMA, WiMAX, LTE, Ev-DO, and others.

The term “processor” may refer to any device or portion of a device that processes electronic data from registers and/or memory to transform that electronic data into other electronic data that may be stored in registers and/or memory.

At least one of the integrated circuit components may shielded from radio frequency/electromagnetic interference with an electromagnetic shielding structure comprising a planar structure and at least one footing projecting from the planar structure, wherein at least one of the planar structure and the at least one footing comprises a heat resistant plastic and an electrically conductive material abutting at least a portion of the heat resistant plastic.

In various implementations, the computing device may be a laptop, a netbook, a notebook, an ultrabook, a smartphone, a tablet, a personal digital assistant (PDA), an ultra-mobile PC, a mobile phone, a desktop computer, a server, a printer, a scanner, a monitor, a set-top box, an entertainment control unit, a digital camera, a portable music player, or a digital video recorder. In further implementations, the computing device may be any other electronic device that processes data.

It is understood that the subject matter of the present description is not necessarily limited to specific applications illustrated in FIGS. 1-18. The subject matter may be applied to other integrated circuit devices and assembly applications, as well as any appropriate electronic application, as will be understood to those skilled in the art.

The follow examples pertain to further embodiments and specifics in the examples may be used anywhere in one or more embodiments, wherein Example 1 is an electromagnetic shielding structure, comprising a planar structure and at least one footing projecting from the planar structure, wherein at least one of the planar structure and the at least one footing comprises a heat resistant plastic core and an electrically conductive material abutting at least a portion of the heat resistant plastic core.

In Example 2, the subject matter of Example 1 can optionally include the plastic core comprising a liquid crystal polymer with a glass fiber filler material.

In Example 3, the subject matter of any of Example 1 to 2 can optionally include the electrically conductive material comprising metal.

In Example 4, the subject matter of any of Example 1 to 3 can optionally include the plastic core including at least one opening extending therethrough.

In Example 5, the subject matter of any of Examples 1 to 4 can optionally include the electrically conductive material substantially completely encapsulating the plastic core.

In Example 6, the subject matter of any of Examples 1 to 5 can optionally include the electromagnetic shielding structure being thermally conductive.

Example 7 is an integrated circuit assembly, comprising an electronic substrate, at least one integrated circuit device electrically attached to the electronic substrate, at least one integrated circuit device attached to the electronic substrate adjacent to the at least one integrated circuit device, and an electromagnetic shielding structure electrically attached to the electronic substrate, wherein the electromagnetic shielding structure comprises a planar structure and at least one footing projecting from the planar structure, wherein at least one of the planar structure and the at least one footing comprises a heat resistant plastic core, and an electrically conductive material abutting at least a portion of the plastic core.

In Example 8, the subject matter of Example 7 can optionally include the plastic core comprising a liquid crystal polymer with a glass fiber filler material.

In Example 9, the subject matter of any of Example 7 to 8 can optionally include the electrically conductive material comprising metal.

In Example 10, the subject matter of any of Example 7 to 9 can optionally include the plastic core including at least one opening extending therethrough.

In Example 11, the subject matter of any of Examples 7 to 10 can optionally include a heat dissipation device and a thermal interface material, wherein the thermal interface material extends through the opening between the integrated circuit device and the heat dissipation device.

In Example 12, the subject matter of any of Examples 7 to 11 can optionally include the electrically conductive material substantially completely encapsulating the plastic core.

In Example 13, the subject matter of any of Examples 7 to 12 can optionally include the electromagnetic shielding structure being electrically attached to a ground of the electronic substrate.

In Example 14, the subject matter of any of Examples 7 to 13 can optionally include the electromagnetic shielding structure being thermally conductive.

In Example 15, the subject matter of Example 14 can optionally include a thermal interface material between the electromagnetic shielding structure and the integrated circuit device.

Example 16 is an electronic system comprising a board; and an integrated circuit package electrically attached to the board, wherein the integrated circuit assembly comprises an integrated circuit assembly, comprising an electronic substrate, at least one integrated circuit device electrically attached to the electronic substrate, at least one integrated circuit device attached to the electronic substrate adjacent to the at least one integrated circuit device, and an electromagnetic shielding structure electrically attached to the electronic substrate, wherein the electromagnetic shielding structure comprises a planar structure and at least one footing projecting from the planar structure, wherein at least one of the planar structure and the at least one footing comprises a heat resistant plastic core and an electrically conductive material abutting at least a portion of the heat resistant plastic core.

In Example 17, the subject matter of Example 16 can optionally include the heat resistant plastic core comprising a liquid crystal polymer with a glass fiber filler material.

In Example 18, the subject matter of any of Example 16 to 17 can optionally include the electrically conductive material comprising metal.

In Example 19, the subject matter of any of Example 16 to 18 can optionally include the heat resistant plastic core including at least one opening extending therethrough.

In Example 20, the subject matter of any of Examples 16 to 19 can optionally include a heat dissipation device and a thermal interface material, wherein the thermal interface material extends through the opening between the integrated circuit device and the heat dissipation device.

In Example 21, the subject matter of any of Examples 16 to 20 can optionally include the electrically conductive material substantially completely encapsulating the heat resistant plastic core.

In Example 22, the subject matter of any of Examples 16 to 21 can optionally include the electromagnetic shielding structure being electrically attached to a ground of the electronic substrate.

In Example 23, the subject matter of any of Examples 16 to 22 can optionally include the electromagnetic shielding structure being thermally conductive.

In Example 24, the subject matter of Example 23 can optionally include a thermal interface material between the electromagnetic shielding structure and the integrated circuit device.

Example 25 is a method of fabrication an integrated circuit assembly may comprise forming an electronic substrate, forming at least one integrated circuit device, electrically attaching the at least one integrated circuit device to the electronic substrate, electrically attaching the at least one integrated circuit device to the electronic substrate, forming at least one electromagnetic interference structure by forming a planar structure and at least one footing projecting from the planar structure, wherein at least one of the planar structure and the at least one footing comprises a heat resistant plastic core, and forming an electrically conductive material abutting at least a portion of the heat resistant plastic core; and electrically attaching the electromagnetic shielding structure to the electronic substrate adjacent to the at least one integrated circuit device.

In Example 26, the subject matter of Example 25 can optionally include forming the heat resistant plastic core from a liquid crystal polymer with a glass fiber filler material.

In Example 27, the subject matter of any of Example 25 to 26 can optionally include forming the electrically conductive material from metal.

In Example 28, the subject matter of any of Example 25 to 27 can optionally include forming the heat resistant plastic core with at least one opening extending therethrough.

In Example 29, the subject matter of any of Examples 25 to 28 can optionally include forming a heat dissipation device and forming a thermal interface material, wherein the thermal interface material extends through the opening between the integrated circuit device and the heat dissipation device.

In Example 30, the subject matter of any of Examples 25 to 29 can optionally include forming the electrically conductive material substantially completely encapsulating the heat resistant plastic core.

In Example 31, the subject matter of any of Examples 25 to 30 can optionally include electrically attaching the electromagnetic shielding structure to a ground of the electronic substrate.

In Example 32, the subject matter of any of Examples 16 to 31 can optionally include forming the electromagnetic shielding structure from at least one thermally conductive material.

In Example 33, the subject matter of Example 32 can optionally include disposing a thermal interface material between the electromagnetic shielding structure and the integrated circuit device.

Having thus described in detail embodiments of the present invention, it is understood that the invention defined by the appended claims is not to be limited by particular details set forth in the above description, as many apparent variations thereof are possible without departing from the spirit or scope thereof.

What is claimed is:

1. An electromagnetic shielding structure comprising:
a planar structure; and
at least one footing projecting from the planar structure, wherein at least one of the planar structure and the at least one footing comprises a heat resistant plastic core and an electrically conductive material abutting at least a portion of the heat resistance plastic core.

2. The electromagnetic shielding structure of claim 1, wherein the heat resistance plastic core comprises a liquid crystal polymer with a glass fiber filler material.

3. The electromagnetic shielding structure of claim 1, wherein the electric conductive material comprises metal.

4. The electromagnetic shielding structure of claim 1, wherein the heat resistant plastic core includes at least one opening extending therethrough.

5. The electromagnetic shielding structure of claim 1, wherein the electrically conductive material substantially completely encapsulates the heat resistant plastic core.

6. The electromagnetic shielding structure of claim 1, wherein the electromagnetic shielding structure is thermally conductive.

7. An integrated circuit assembly, comprising:
an electronic substrate;
at least one integrated circuit device electrically attached to the electronic substrate; and
an electromagnetic shielding structure electrically attached to the electronic substrate adjacent to the at least integrated circuit device, wherein the electromagnetic shielding structure comprises a planar structure and at least one extension projecting from the planar structure, wherein at least one of the planar structure and the at least one footing comprises a heat resistant plastic core and an electrically conductive material abutting at least a portion of the heat resistant plastic core.

8. The integrated circuit assembly of claim 7, wherein the heat resistant plastic core comprises a liquid crystal polymer with a glass fiber filler material.

9. The integrated circuit assembly of claim 7, wherein the electric conductive material comprises metal.

10. The integrated circuit assembly of claim 7, wherein the heat resistant plastic core includes at least one opening extending therethrough.

11. The integrated circuit assembly of claim 10, further including a heat dissipation device and a thermal interface material, wherein the thermal interface material extends through the opening between the integrated circuit device and the heat dissipation device.

12. The integrated circuit assembly of claim 7, wherein the electrically conductive material substantially completely encapsulates the heat resistant plastic core.

13. The integrated circuit assembly of claim 7, wherein the electromagnetic shielding structure is thermally conductive.

14. An electronic system, comprising:
a board; and
an integrated circuit package electrically attached to the board, wherein the integrated circuit package comprises:
an electronic substrate;
at least one integrated circuit device electrically attached to the electronic substrate; and
an electromagnetic shielding structure attached to the electronic substrate adjacent to the at least integrated circuit device, wherein the electromagnetic shielding structure comprises a planar structure and at least one footing projecting from the planar structure, wherein at least one of the planar structure and at least one footing comprises a heat resistant plastic core and an electrically conductive material abutting at least a portion of the heat resistant plastic core.

15. The electronic system of claim 14, wherein the heat resistant plastic core comprises a liquid crystal polymer with a glass fiber filler material.

16. The electronic system of claim 14, wherein the electric conductive material comprises metal.

17. The electronic system of claim 14, wherein the heat resistant plastic core includes at least one opening extending therethrough.

18. The electronic system of claim 17, further including a heat dissipation device and thermal interface material, wherein the thermal interface material extends through the opening between the integrated circuit device and the heat dissipation device.

19. The electronic system of claim 14, wherein the electromagnetic shielding structure is thermally conductive.

20. A method of fabricating an integrated circuit assembly, comprising:
forming an electronic substrate;
forming at least one integrated circuit device;
electrically attaching the at least one integrated circuit device to the electronic substrate;
forming at least one electromagnetic interference structure by forming a planar structure and at least one footing projecting from the planar structure, wherein at least one of the planar structure and the at least one footing comprises a heat resistant plastic core, and forming an electrically conductive material abutting at least a portion of the heat resistant plastic core; and
electrically attaching the electromagnetic shielding structure to the electronic substrate adjacent to the at least one integrated circuit device.

21. The method of claim 20, wherein forming the heat resistant plastic core comprises forming the heat resistant plastic core from a liquid crystal polymer with a glass fiber filler material.

22. The method of claim 20, wherein forming the electrically conductive material comprises forming the electrically conductive material from metal.

23. The method of claim 20, wherein forming the heat resistant plastic core includes forming at least one opening extending therethrough.

24. The method of claim 23, further including forming a heat dissipation device and forming a thermal interface material, wherein the thermal interface material extends through the at least one opening between the integrated circuit device and the heat dissipation device.

25. The method of claim 20, wherein forming the electromagnetic shielding structure comprises forming the electromagnetic shielding structure from at least one thermally conductive material.
